(19) United States
(12) Patent Application Publication
(10) Pub. No.: US 2014/0239395 A1
(43) Pub. Date: Aug. 28, 2014

(54) CONTACT RESISTANCE REDUCTION IN FINFETS

(71) Applicants: INTERNATIONAL BUSINESS MACHINES CORPORATION, Armonk, NY (US); STMicroelectronics, Inc., Coppell, TX (US)

(72) Inventors: Veeraraghavan S. Basker, Schenectady, NY (US); Qing Liu, Guilderland, NY (US); Tenko Yamashita, Schenectady, NY (US); Chun-Chen Yeh, Clifton Park, NY (US)

(21) Appl. No.: 13/775,946

(22) Filed: Feb. 25, 2013

(51) Int. Cl. H01L 29/66; H01L 29/78

(52) U.S. Cl. CPC H01L 29/66795; H01L 29/785
USPC 257/347; 438/157

(57) ABSTRACT

A method for forming contacts in a semiconductor device includes forming a plurality of substantially parallel semiconductor fins on a dielectric layer of a substrate having a gate structure formed transversely to a longitudinal axis of the fins. The fins are merged by epitaxially growing a crystalline material between the fins. A field dielectric layer is deposited over the fins and the crystalline material. Trenches that run transversely to the longitudinal axis of the fins are formed to expose the fins in the trenches. An interface layer is formed over portions of the fins exposed in the trenches. Contact lines are formed in the trenches that contact a top surface of the interface layer on the fins and at least a portion of side surfaces of the interface layer on the fins.

### BACKGROUND

1. Technical Field

The present invention relates to semiconductor processing, and more particularly to devices and methods for forming contacts for fin transistors with reduced contact resistance.

2. Description of the Related Art

High contact resistance results in loss of performance, errors in data and increased heat and power loss, to name a few effects. Contact resistance in semiconductor devices increases dramatically with reduction in pitch scaling sizes. Smaller contact areas result in rapid increases in contact resistance. With nanometer scale structures, such as fins for fin field effect transistors, smaller three-dimensional structures present particular difficulties in forming suitable contact areas to make adequate electrical contact.

### SUMMARY

A method for forming contacts in a semiconductor device includes forming a plurality of substantially parallel semiconductor fins on a dielectric layer of a substrate having a gate structure formed transversely to a longitudinal axis of the fins. The fins are merged by epitaxially growing a crystalline material between the fins. A field dielectric layer is deposited over the fins and the crystalline material. Trenches that run transversely to the longitudinal axis of the fins are formed to expose the fins in the trenches. An interface layer is formed over portions of the fins exposed in the trenches. Contact lines are formed in the trenches that contact a top surface of the interface layer on the fins and at least a portion of side surfaces of the interface layer on the fins.

Another method for forming a contact in a semiconductor device includes forming a plurality of substantially parallel semiconductor fins on a dielectric layer of a substrate; forming a dummy gate structure transversely to a longitudinal axis of the fins; merging the fins by epitaxially growing a crystalline material between the fins; planarizing a field dielectric layer over the fins and the crystalline material to expose a dummy gate; replacing the dummy gate with a gate conductor; forming trenches that run transversely to the longitudinal axis of the fins and extend through the field dielectric layer and into the crystalline material, the trenches being formed selectively to the fins to maintain the fins intact and to expose the fins in the trenches; forming a conductive interface layer over portions of the fins exposed in the trenches; and forming contact lines in the trenches that contact a top surface of the interface layer on the fins and at least a portion of side surfaces of the interface layer on the fins.

A semiconductor device having fin transistors includes a plurality of substantially parallel semiconductor fins formed over a substrate and a gate structure formed over the fins transversely to a longitudinal axis of the fins. Source and drain regions are formed on opposite sides of the gate structure and are merged with the fins by an epitaxially grown crystalline material between the fins in merged regions. Interface layers are formed on the fins in regions disposed apart from both sides of the gate structure. The interface layers are formed over a top and at least a portion of opposing sides of the fins. Contact lines are formed over the interface layers such that contact is made at the top surface of the interface layer on the fins and at least a portion of the sides of the interface layer on the fins.

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1 is a top view of a semiconductor device showing a gate structure with fins disposed transversely therethrough in accordance with the present principles;

FIG. 2 is a top view of the semiconductor device of FIG. 1 showing the fins merged by growing a doped material to form source and drain regions in accordance with the present principles;

FIG. 3 is a top view of the semiconductor device of FIG. 2 showing second spacers formed on the gate structure in accordance with the present principles;

FIG. 4 is a top view of the semiconductor device of FIG. 3 showing trenches formed in a field dielectric (not shown) in accordance with the present principles;

FIG. 5 is a top view of the semiconductor device of FIG. 4 showing an interface layer formed on fins in the trenches in accordance with the present principles;

FIG. 6 is a top view of the semiconductor device of FIG. 5 showing a contact line formed on the interface layer of the fins in the trenches in accordance with the present principles;

FIG. 7 is a perspective view of a semiconductor device having a mask stack formed on a semiconductor on insulator substrate in accordance with one illustrative embodiment;

FIG. 8 is a perspective view of the semiconductor device of FIG. 7 having mandrels and sidewall spacers formed on the mask stack for spacer image transfer (SIT) processing to form fins in accordance with one illustrative embodiment;

FIG. 9 is a perspective view of the semiconductor device of FIG. 8 having fin structures cut through etching in accordance with one illustrative embodiment;

FIG. 10 is a perspective view of the semiconductor device of FIG. 9 having a dummy gate structure formed over the fin structures in accordance with one illustrative embodiment;

FIG. 11 is a perspective view of the semiconductor device of FIG. 10 having first spacers formed for the dummy gate structure in accordance with one illustrative embodiment;

FIG. 12 is a side perspective view of the semiconductor device of FIG. 11 in accordance with one illustrative embodiment;

FIG. 13 is a perspective view of the semiconductor device of FIG. 11 having a crystalline material epitaxially grown to merge the fins in accordance with one illustrative embodiment;

FIG. 14 is a side perspective view of the semiconductor device of FIG. 13 showing the crystalline material grown to a height of a mask layer in accordance with one illustrative embodiment;

FIG. 15 is a perspective view of the semiconductor device of FIG. 13 rotated clockwise by 90 degrees and showing second spacers formed on the dummy gate structure in accordance with one illustrative embodiment;

FIG. 16 is a perspective view of the semiconductor device of FIG. 15 showing formation and planarization of a field dielectric layer and the replacement of the dummy gate in accordance with one illustrative embodiment;

FIG. 17 is a perspective view of the semiconductor device of FIG. 16 showing formation of trenches to expose fins in accordance with one illustrative embodiment;

FIG. 18 is a side perspective view of the semiconductor device of FIG. 17 showing the trenches with exposed fins therein in accordance with one illustrative embodiment;

FIG. 19 is a cross-sectional view taken at section line 19-19 of FIG. 17 showing an interface layer formed on the fins in accordance with one illustrative embodiment;

FIG. 20 is a cross-sectional view taken at section line 19-19 of FIG. 17 showing a contact line formed over the interface layer formed on the fins in accordance with one illustrative embodiment; and

FIG. 21 is a block/flow diagram showing a method for reducing contact resistance in accordance with illustrative embodiments.

### DETAILED DESCRIPTION OF PREFERRED EMBODIMENTS

In accordance with the present principles, contact areas are increased by taking advantage of the surfaces provided by three-dimensional structures. In one particularly useful embodiment, the three-dimensional structures include fins formed in semiconductor material. Contact structures are formed in contact with the fins along with a higher conductivity material that is employed to wrap around the fin and make contact with the higher conductivity material. By increasing the effective area of the contact, contact resistance can be maintained or increased despite further reductions in pitch or device size.

The present aspects will be described in terms of fin structures employed for fin field effect transistors (finFETs); however, any three-dimensional structure may benefit from the decrease in contact resistance in accordance with the present principles.

It is to be understood that the present invention will be described in terms of a given illustrative architecture having a wafer with three-dimensional structures formed thereon; however, other architectures, structures, substrate materials and process features and steps may be varied within the scope of the present invention.

It will also be understood that when an element such as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

A design for an integrated circuit chip may be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer may transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements may be included in the compound, such as, e.g., different dopant levels, and still function in accordance with the present principles. The compounds with additional elements may be referred to herein as alloys.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended, as readily apparent by one of ordinary skill in this and related arts, for as many items listed.

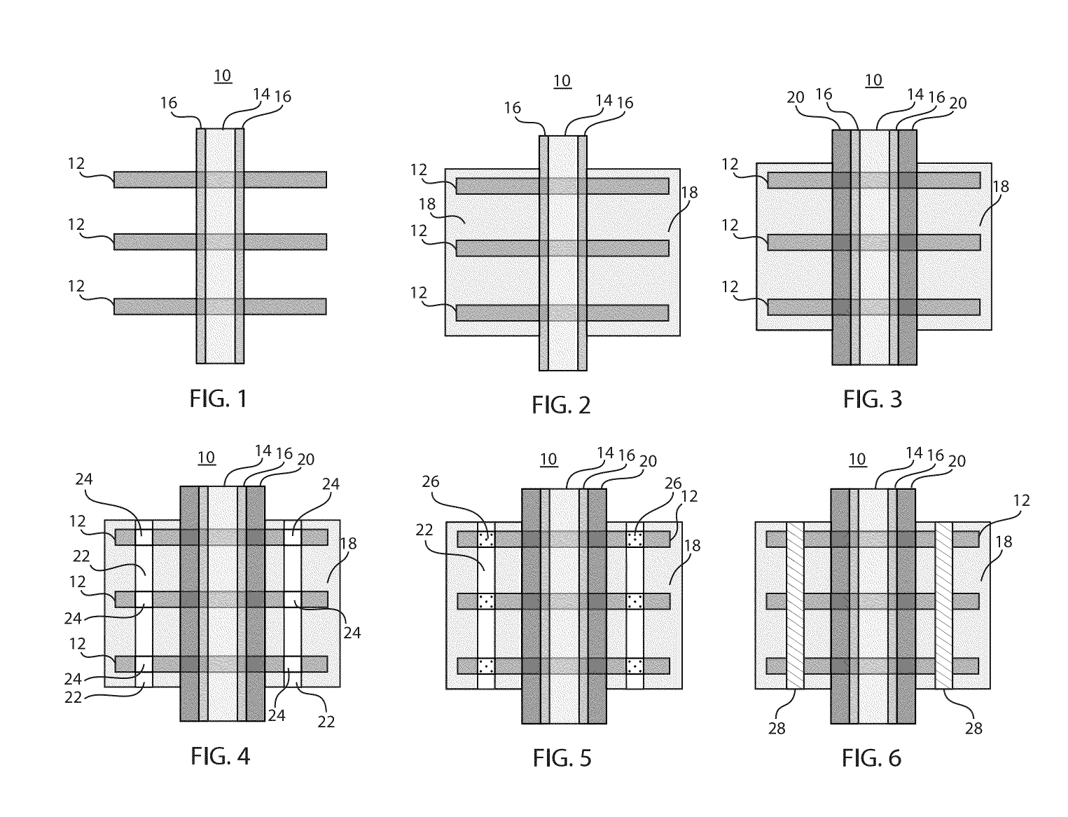

Referring now to the drawings in which like numerals represent the same or similar elements and initially to FIG. 1, a top view of a semiconductor substrate 10 is depicted to illustratively demonstrate a method for forming contacts with reduced contact resistance. The substrate 10 may include a bulk substrate or a semiconductor on insulator substrate (SOI). The substrate 10 may include a monocrystalline semiconductor material, such as silicon, silicon germanium, silicon carbide, etc. A plurality of fins 12 are formed over the substrate or a buried dielectric layer. The fins 12 are also preferably formed from a crystalline material, such as Si, SiGe, etc. The fins 12 may be undoped.

A dummy gate 14 is formed over the fins 12 from a selectively removable material such as polysilicon. The dummy gate 14 is patterned to form lines traverse to the fins 12. Sidewall spacers 16 are formed on sides of the dummy gate 14. The sidewall spacers 16 may include a silicon nitride.

Referring to FIG. 2, according to one illustrative embodiment, source and drain regions are formed by epitaxially growing a doped material 18 to merge the fins 12. The material may include SiGe if, e.g., the fins are formed from Si or SiGe. The fins 12 act as seed material for growing the material 18.

Referring to FIG. 3, a second sidewall spacer 20 is formed by a deposition process followed by a reactive ion etch. The second sidewall spacer 20 may also include a silicon nitride material.

Referring to FIG. 4, a field oxide (not shown) is formed over the doped material 18 and the fins 12. The field oxide and the doped material 18 are patterned to form trenches 22 that expose the fins 12 in portions 24 down to the underlying dielectric under the fins 12 (e.g., buried oxide).

Referring to FIG. 5, an interface layer 26 is formed on exposed fins. This may include depositing a metal, e.g., Ni, in the trenches 22 and annealing to mix with the metal with the fins 12, e.g., to form a silicide over a top and sides of the fins 12 (wrap around three sides of the fins 12). In alternate embodiments, a metal silicide, e.g., NiSi may be sputtered or otherwise deposited over the exposed portions 24 of the fins. The metal and/or access material is then removed. The trenches 22 may now be filled with a dielectric material, with a doped material or with the material for contact lines. This will depend on the design.

Referring to FIG. 6, contact lines or contacts 28 are formed on a top surface of the fins 12 within the field oxide or other dielectric material. As mentioned, the contacts 28 may surround three sides of the fins 12 or simply contact a top surface of the fins 12 (e.g., the fins may again be merged with doped material 18 or the spaces between the fins 12 may be filled with a different material). In one embodiment, the filler material may fill only a portion of the fin height to permit only a portion of the sidewalls of the fin 12 to be contacted by the contacts 28.

By forming the silicided tops and sidewalls of the fins 12, the conductivity is improved. Further, the intermixing of metal in the silicide provides better bonding to the material of the contacts 28. In addition, the surface area of contact is effectively increased. These aspects all contribute to a significant reduction in contact resistance over conventional schemes. This further enables scaling of the size of the technology without contact resistance acting as a bottleneck.

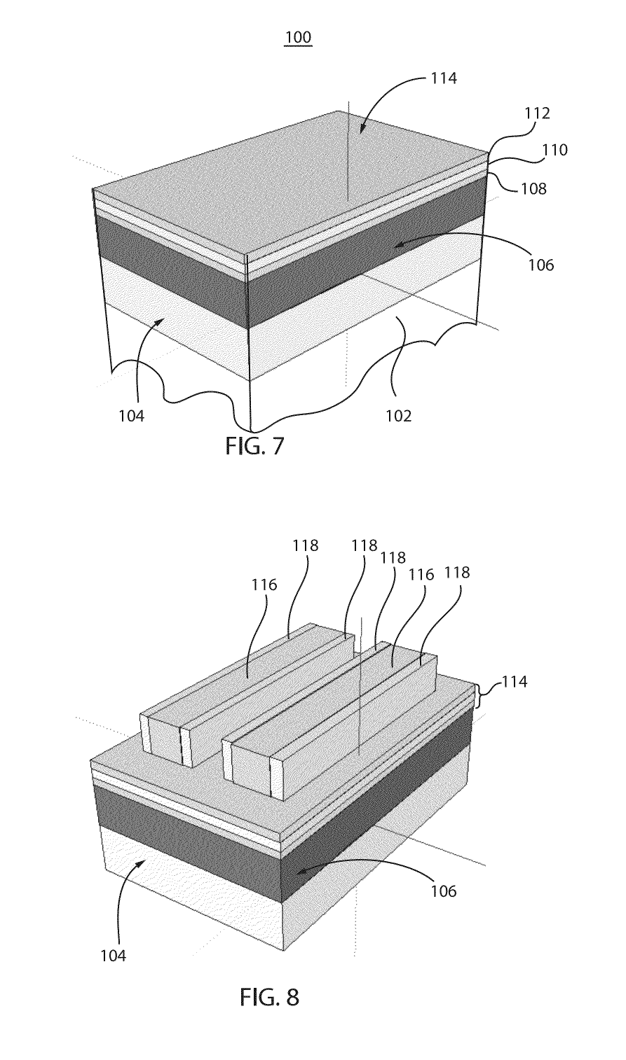

FIGS. 7-19 show a more detailed embodiment of the present principles using three-dimensional representations to provide a clearer understanding of aspects of the present invention. Referring to FIG. 7, a SOI substrate 100 is shown having a mask stack (e.g., hard mask stack) 114 formed thereon. The SOI substrate 100 includes a base substrate 102, which may include any suitable substrate material, e.g., Si, Ge, SiGe, GaAs, etc. The base substrate 102 may include a monocrystalline substrate although other morphologies may be employed. A buried dielectric layer 104 may include an oxide, although other dielectric materials may be employed as well. A semiconductor layer 106 is provided on the buried dielectric layer 104. The semiconductor layer 106 may include Si, SiGe, Ge, etc., although monocrystalline Si is preferred.

The mask stack 114 may include three layers, which will be employed for different purposes during processing. In one embodiment, the stack 104 includes a nitride layer 108, an oxide layer 110 and a nitride layer 112 (NON stack). Other dielectric materials may be employed and may be employed in a different order. The layers should be selectively etchable relative to adjacent layers.

Referring to FIG. 8, sub-minimum feature sized fins may be formed using sidewall image transfer (SIT) processing. This includes the formation of mandrels 116 by depositing, e.g., polysilicon, and patterning the material of the mandrels 116. A dielectric layer, e.g., a nitride, is deposited and etched to form sidewall spacers 118.

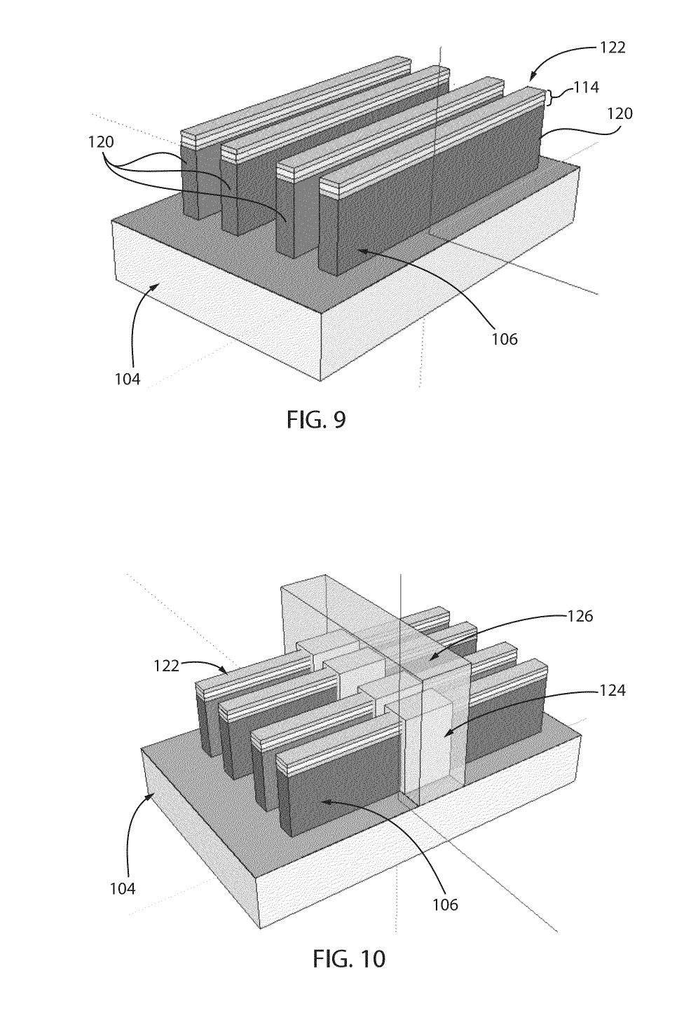

Referring to FIG. 9, the mandrels 116 are etched away leaving the sidewall spacers 118, which will be employed as an etch mask to etch through the stack 114 and the semiconductor layer 106 to from structures 122. The portions of the semiconductor layer 106 in the structures 122 will become fins 120.

The fin cut process may employ other known techniques, e.g., an optical dispersive layer (ODL) and a Si antireflection coating (SiARC) layer may be formed and provide the image layer. The image layer acts as an etch mask to cut the fins.

Referring to FIG. 10, a gate dielectric 124 and a dummy gate 126 are formed over the fin structures 122. There are a number of ways to form the gate structures and the gate structures may include different materials and different material combinations. For illustrative purposes, the gate structure employed here will include a high dielectric constant material/metal gate structure (HKMG). In this case, the high dielectric constant material may include silicon nitride, silicon oxynitride, silicon oxide, hafnium dioxide, etc. The dummy gate 126 will eventually be removed and replaced by a metal conductor, such as, e.g., Al, Cu, etc. The gate dielectric 124 and the dummy gate 126 are blanket deposited and anisotropically etched, e.g., a reactive ion etch (RIE). The layer 112 of the mask stack 114 is employed to protect the underlying layers 110, 108 and fin 120. It should be noted that in some embodiments, a dummy gate is not employed and that a gate conductor is formed instead.

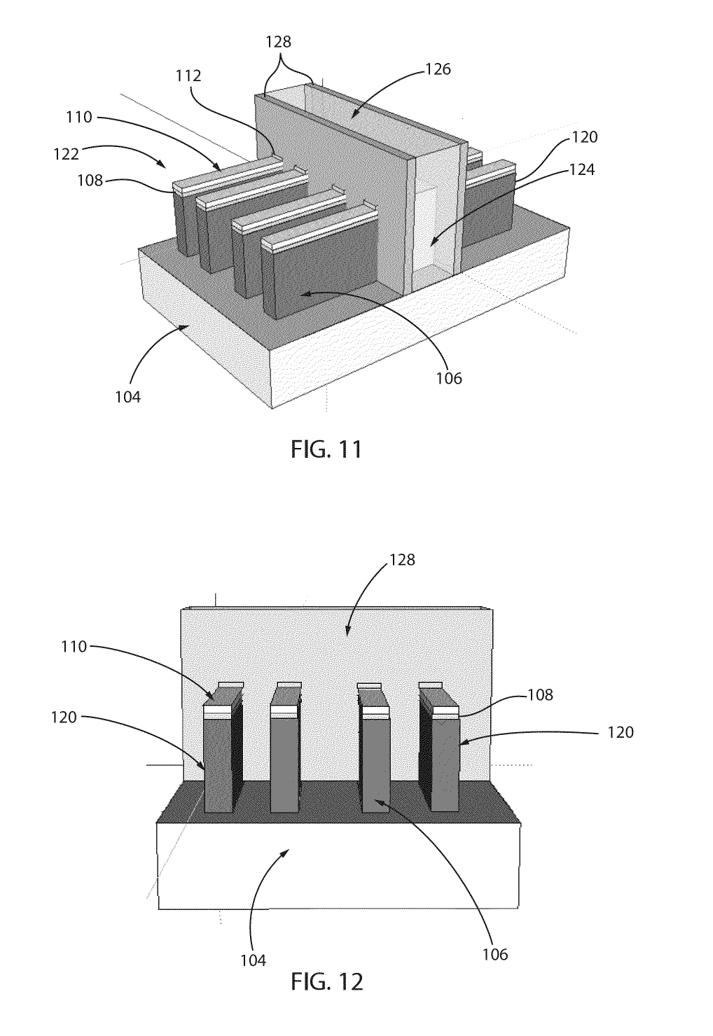

Referring to FIG. 11, sidewall spacers 128 are formed by depositing a dielectric material, such as, e.g., silicon nitride, and performing an RIE process. The RIE also removes the layer 112, which may also include silicon nitride.

Referring to FIG. 12, a side perspective of FIG. 11 is shown to depict the removal of layer 112. Layer 112 is recessed back to the sidewall spacers 128, and the remaining layers 108, 110 and 120 remain intact.

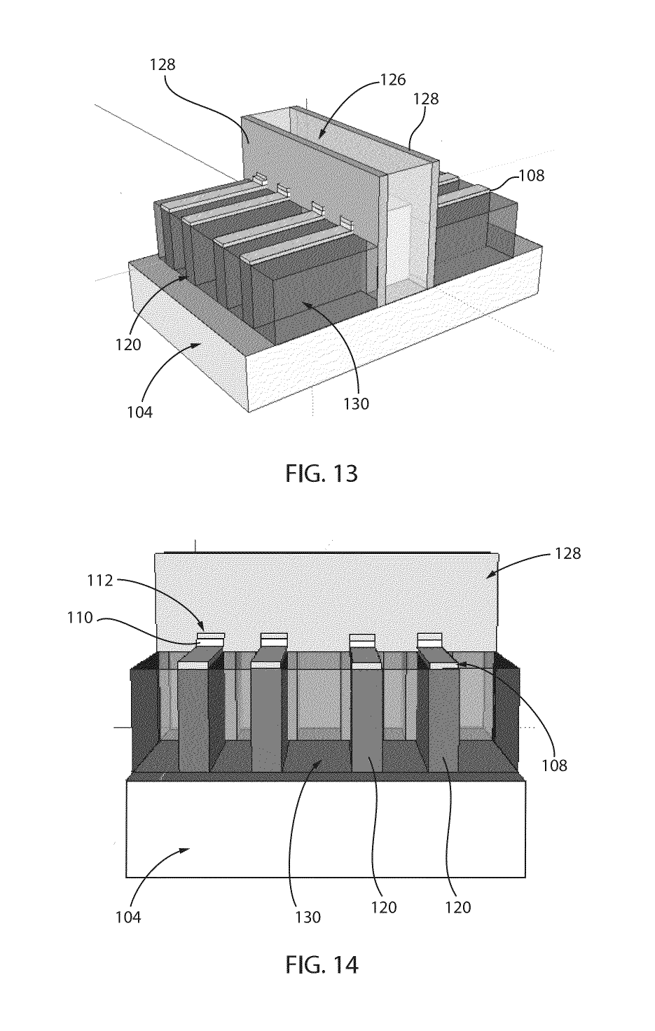

Referring to FIG. 13, surfaces of the fins 120 need to be pre-cleaned prior to epitaxial growth. During the pre-clean process, which includes an etching process, such as a wet or dry etch to remove oxide and contaminants from the fins 120, the layer 110 is removed. The layer 110 may include an oxide as well. This exposes the layer 108, which is employed to prevent epitaxial growth from a top surface of the fin 120 during the epitaxial growth process.

An island-size distributed (ISD) epitaxial growth process is performed to grow material 130 to merge the fins 120. The material 130 may include, e.g., SiGe, Si, or Ge. The material 130 grows to the bottom of the layer 108, as depicted in FIG. 14. The layer 108 prevents epitaxial growth from the top of the fin 120 and minimizes epitaxial overburden. The material 130 may be doped in-situ or doped after formation. Different regions may be masked during epitaxial growth to separately form source regions and drain regions in the material 130.

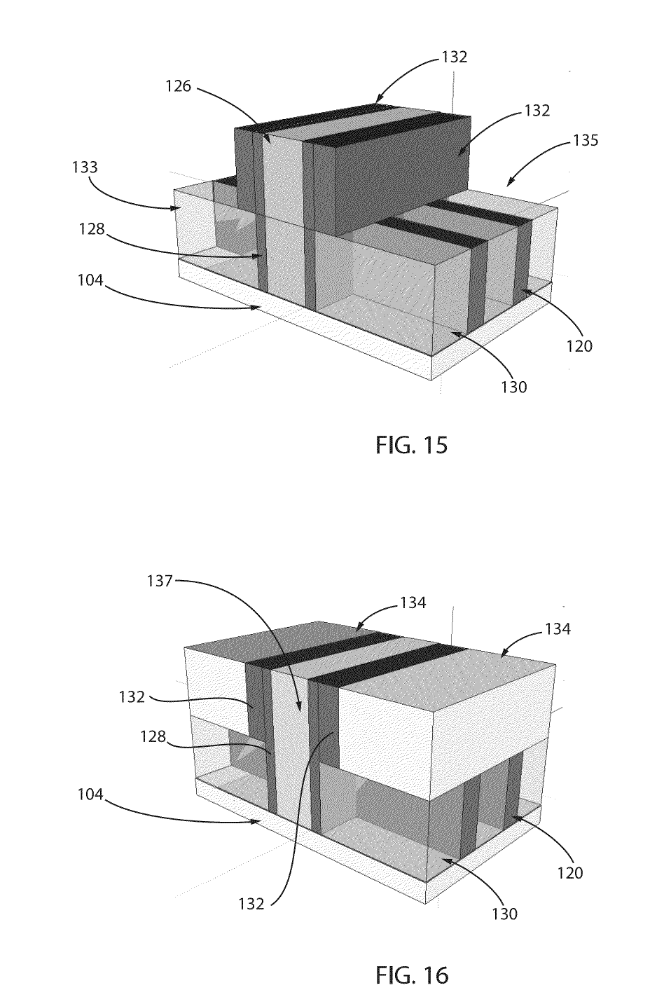

Referring to FIG. 15, second sidewall spacers 132 are formed by depositing a dielectric material, e.g., silicon nitride, and performing a RIE. An anneal is performed to activate the source and drain regions 133 and 135.

Referring to FIG. 16, a field dielectric layer 134 is formed over the entire surface and planarized to the dummy gate 126. The dielectric layer 134 may include an oxide, such as a silicon oxide. The dummy gate 126 is removed followed by deposition and planarization of a gate conductor 137. The gate conductor 137 may include Al, Cu or any other suitable conductor. The planarization steps may include chemical mechanical polishing (CMP) or the like.

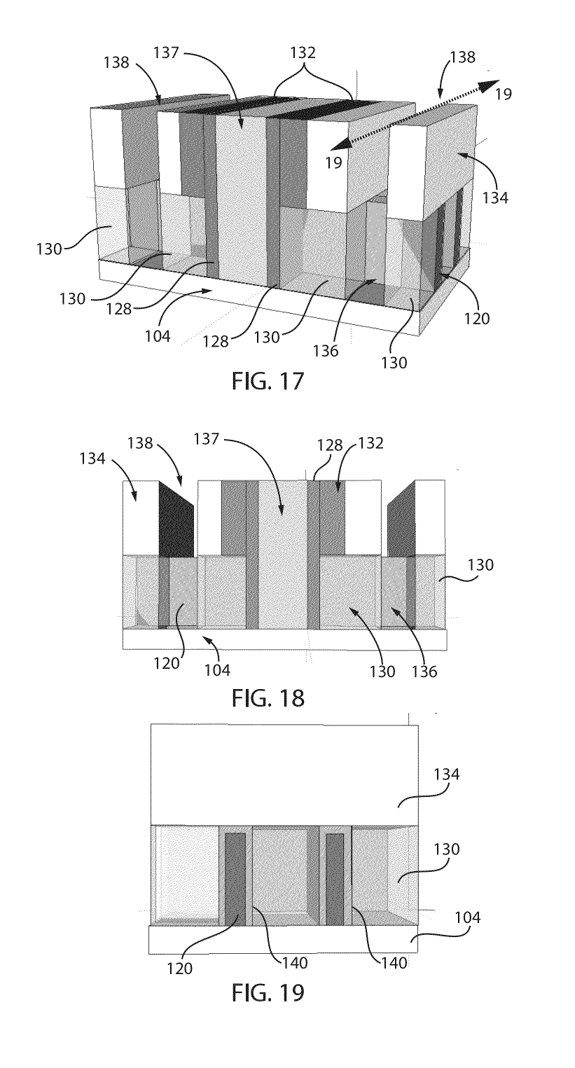

Referring to FIG. 17, after etch masking the dielectric layer 134, trenches 138 are etched through the dielectric layer 134 and etched selectively to the fins 120, through the semiconductor material 130. The etch is preferably a selective RIE which leaves the fins 120 intact. The fins 120 are now exposed in portions 136. FIG. 18 shows a side perspective view along/down the trenches 138 to give a better view of the exposed portions 136 of the fins 120.

Referring to FIG. 19, a cross-sectional view taken at section line 19-19 of FIG. 17 shows the fins 120 after a conductive interface layer 140 is formed around the fins 120. Note that the interface layer 140 has not yet been formed in FIG. 17. The interface layer 140 may be formed using siliciding techniques known in the art. In one embodiment, a metal layer, such as e.g., Ni, Pt, Ti, W or the like is deposited over the exposed portions 136 of the fins 120 in the trenches 138. An anneal process is performed to diffuse metal into the fins 120 to form the silicide for the interface layer 140 over the top and sides of each fin 120. The fins 120 remain intact and have a highly conductive silicide wrapped around the exposed outer surface of the fin 120.

In one embodiment, silicide formation begins with a preclean, which is followed by a metal-silicon compound sputtering (e.g., NiSi sputtering). A rapid thermal anneal is performed to form the silicide then followed by a wet etch to remove the residual metal. In either embodiment, a target thickness is about 8 to 20 nm, and more preferably about 10-12 nm. The silicide forms an ohmic contact between the contacts and the transistor source/drain regions (e.g., silicon). While a silicide is preferred, metal conductors may be employed to clad portions 136 to form an interface layer 140.

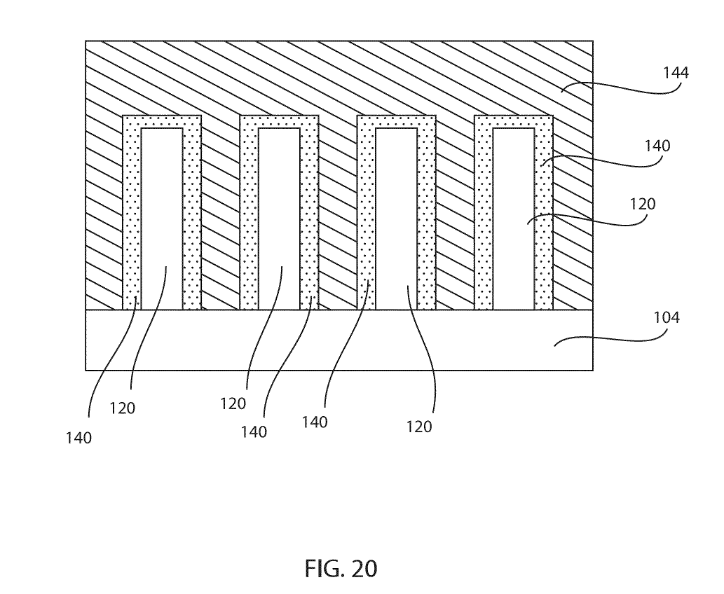

Referring to FIG. 20, another cross-sectional view shows a contact line 144 formed in contact with the interface layer 140 at the tops and side portions the fins 120. In accordance with the present principles, the contact resistance is significantly lowered between the fin 120 and the contact line 144. This is due to the increased conductivity of the interface layer 140 and that the interface layer 140 is intermixed with the fin 120. Further, the contact area is also significantly increased. The interface layer 140 increases the effective size of the fin 120 and the contact line 144 is in contact with the interface layer 140 of the fin 120 on three sides. The contact line also directly contacts at least some of the material 130 for the source and drain regions. Reduction in contact resistance may be decreased by at least 10-15%. In addition, the structure in accordance with the present embodiments enables reduction in device scale to feature sizes of less than 25 nm without contact resistance becoming a bottleneck that would limit device scaling. Simulation data in accordance with the present principles provides that contact resistance may be maintained at, e.g., 50 ohm/micron even with feature sizes down to 25 nm.

It should be understood that while it is preferable that the contact line 144 contacts the interface layer 140 on the top and along the sides of the fin 120. In some embodiments, it may be advantageous to have the spaces between fins 120 partially filled and provide a contact line to only the top side of the fin 102 or to the top side and a portion of the depth along the sides of fin 120. The spaces between the fins 120 may be filled by epitaxially regrowing the material 130, filling the spaces with a dielectric material or not completely etching/removing the material 130 to expose the fin completely. If the material 130 is left to partially fill the depth between the fins 120, the interface layer 144 would also be limited to a partial depth along the sides of the fins 120.

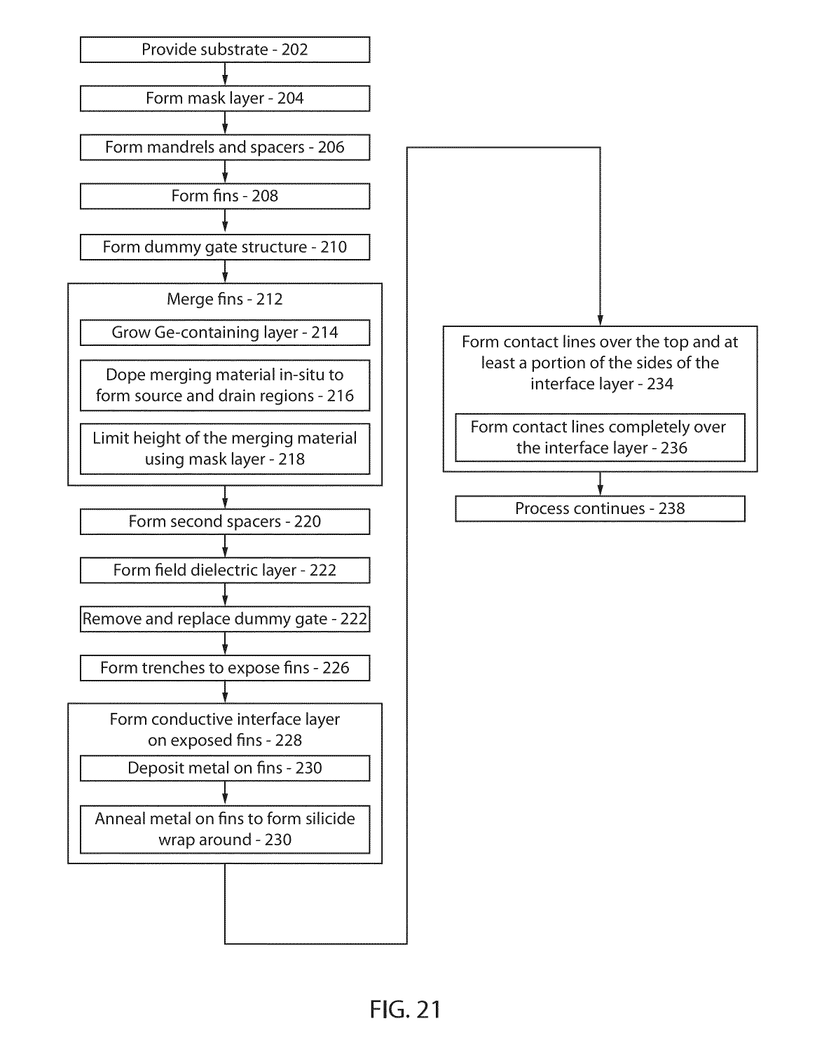

Referring to FIG. 21, a method for forming a contact with reduced contact resistance on a semiconductor device is illustratively shown. It should be noted that, in alternative implementations, the functions noted in the blocks may occur out of the order noted in the FIG. 21. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

In block 202, a SOI (or bulk) substrate is provided. In block 204, a mask layer is formed over the substrate. The mask layer may include a plurality of layers, e.g., a nitride, oxide, nitride stack. In block 206, mandrels and sidewall spacers to the mandrels are formed on the mask layer. The mandrels are then removed. Other patterning techniques may also be employed. In block 208, a plurality of substantially parallel semiconductor fins are formed on or over a substrate by employing a SIT process. In one embodiment, the substrate includes a SOI substrate and the fins are formed from a semiconductor on a buried dielectric layer of the SOI.

In block 210, a dummy gate structure is formed over the fin structures (and the mask layer, if present) transversely to a longitudinal axis of the fins. The dummy gate structure includes a gate dielectric formed over the fins, the dummy gate and first spacers formed on lateral sides of the dummy gate.

In block 212, after a preclean (e.g., etch), the fins are merged by epitaxially growing a crystalline material between the fins. In block 214, the fins may include silicon and the merging of the fins may include epitaxially growing a germanium-containing material between the fins, such as e.g., SiGe. In block 216, the crystalline material may be doped in-situ to form source and drain regions. The source and drain regions may be formed separately by masking off regions on the device so that different dopant conductivities may be provided for the different regions. In block 218, the growth of the crystalline material is limited to a height of the mask layer, which covers the top surface of the fins.

In block 220, second spacers are formed on the first spacers of the dummy gate structure prior to replacing the dummy gate. In block 222, a field dielectric layer is formed over the fins and the crystalline material and is planarized to expose the dummy gate of the dummy gate structure. In block 224, the dummy gate is removed and replaced with a gate conductor. In block 226, trenches are formed that run transversely to the longitudinal axis of the fins and extend through the field dielectric layer and into the crystalline material. The trenches are formed selectively to the fins to maintain the fins intact and to expose the fins in the trenches.

In block 228, a conductive interface layer is formed over portions of the fins exposed in the trenches. The fins may include silicon and forming the interface layer may include depositing a metal or a metal silicon compound over the portions of the fins exposed in the trenches in block 230. The metal or metal-silicon compound is annealed to form a silicide on the top surface and at least a portion of side surfaces of the fins (wrap-around) in block 232.

In block 234, contacts or contact lines are formed in the trenches that contact a top surface of the interface layer on the fins and at least a portion of side surfaces of the interface layer on the fins. In block 236, the contact lines may be formed to completely (or partially) cover the interface layer. In block 238, processing continues to complete upper layers and connections for the device.

Having described preferred embodiments for contact resistance reduction (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

What is claimed is:

1. A method for forming contacts in a semiconductor device, comprising:
forming a plurality of substantially parallel semiconductor fins on a dielectric layer of a substrate having a gate structure formed transversely to a longitudinal axis of the fins;
merging the fins by epitaxially growing a crystalline material between the fins;
depositing a field dielectric layer over the fins and the crystalline material;
forming trenches that run transversely to the longitudinal axis of the fins to expose the fins in the trenches;
forming an interface layer over portions of the fins exposed in the trenches; and
forming contact lines in the trenches that contact a top surface of the interface layer on the fins and at least a portion of side surfaces of the interface layer on the fins.

2. The method as recited in claim 1, wherein the fins include silicon and the step of merging the fins includes epitaxially growing a germanium-containing material between the fins.

3. The method as recited in claim 1, further comprising forming a mask layer on a top surface of the fins and the step of merging the fins further comprises limiting growth of the crystalline material to a height of the mask layer by covering the top surface of the fins.

4. The method as recited in claim 1, wherein the gate structure includes a gate dielectric formed over the fins, a dummy gate and first spacers formed on lateral sides of the dummy gate, wherein the fins run transversely through the dummy gate, the gate dielectric and the first spacers.

5. The method as recited in claim 1, further comprising replacing the dummy gate with a gate conductor after the merging step.

6. The method as recited in claim 1, wherein merging the fins includes doping the crystalline material in-situ to form source and drain regions.

7. The method as recited in claim 1, wherein the fins include silicon and forming the interface layer includes:
depositing a metal over the portions of the fins exposed in the trenches; and
annealing the metal to form a silicide on the top surface and at least a portion of side surfaces of the fins.

8. The method as recited in claim 1, wherein forming contact lines in the trenches includes forming the contact lines to completely cover the interface layer.

9. A method for forming a contact in a semiconductor device, comprising:
forming a plurality of substantially parallel semiconductor fins on a dielectric layer of a substrate;
forming a dummy gate structure transversely to a longitudinal axis of the fins;
merging the fins by epitaxially growing a crystalline material between the fins;
planarizing a field dielectric layer over the fins and the crystalline material to expose a dummy gate;
replacing the dummy gate with a gate conductor;
forming trenches that run transversely to the longitudinal axis of the fins and extend through the field dielectric layer and into the crystalline material, the trenches being formed selectively to the fins to maintain the fins intact and to expose the fins in the trenches;
forming a conductive interface layer over portions of the fins exposed in the trenches; and
forming contact lines in the trenches that contact a top surface of the interface layer on the fins and at least a portion of side surfaces of the interface layer on the fins.

10. The method as recited in claim 9, wherein the fins include silicon and the step of merging the fins includes epitaxially growing a germanium-containing material between the fins.

11. The method as recited in claim 9, further comprising forming a mask layer on a top surface of the fins and the step of merging the fins further comprises limiting growth of the crystalline material to a height of the mask layer by covering the top surface of the fins.

12. The method as recited in claim 9, wherein the dummy gate structure includes a gate dielectric formed over the fins, the dummy gate and first spacers formed on lateral sides of the dummy gate.

13. The method as recited in claim 12, further comprising forming second spacers on the first spacers of the dummy gate structure prior to replacing the dummy gate.

14. The method as recited in claim 9, wherein merging the fins includes doping the crystalline material in-situ to form source and drain regions.

15. The method as recited in claim 9, wherein the fins include silicon and forming the interface layer includes:
depositing a metal over the portions of the fins exposed in the trenches; and
annealing the metal to form a silicide on the top surface and at least a portion of side surfaces of the fins.

16. The method as recited in claim 9, wherein forming contact lines in the trenches includes forming the contact lines to completely cover the interface layer.

17. A semiconductor device having fin transistors, comprising:
a plurality of substantially parallel semiconductor fins formed over a substrate;
a gate structure formed over the fins transversely to a longitudinal axis of the fins;
source and drain regions formed on opposite sides of the gate structure and being merged with the fins by an epitaxially grown crystalline material between the fins in merged regions;
interface layers formed on the fins in regions disposed apart from both sides of the gate structure, the interface layer being formed over a top and at least a portion of opposing sides of the fins; and
contact lines formed over the interface layers such that contact is made at the top surface of the interface layer on the fins and at least a portion of the sides of the interface layer on the fins.

18. The device as recited in claim 17, wherein the fins include Si and the epitaxially grown crystalline material includes doped SiGe.

19. The device as recited in claim 17, wherein the fins include silicon and forming the interface layer includes a silicide formed on the top and the at least a portion of the sides of the fins.

20. The device as recited in claim 17, wherein the contact lines are formed to completely cover the interface layer.
